(19) United States
(12) Patent Application Publication
(10) Pub. No.: US 2024/0074289 A1
(43) Pub. Date: Feb. 29, 2024

(54) INSULATED GLASS UNIT WITH TRANSPARENT OLED PANEL AND MOBILITY SYSTEM INCLUDING THE SAME

(71) Applicant: LG DISPLAY CO., LTD., SEOUL (KR)

(72) Inventors: Kyeonghwan KIM, Paju-si (KR); YoungChun LEE, Paju-si (KR)

(73) Assignee: LG DISPLAY CO., LTD., SEOUL (KR)

(21) Appl. No.: 18/238,644

(22) Filed: Aug. 28, 2023

(30) Foreign Application Priority Data
Aug. 29, 2022 (KR) 10-2022-0108592

(51) Int. Cl. H10K 59/80; B61D 25/00; B61L 15/00; H10K 59/126; H10K 59/131

(52) U.S. Cl. CPC H10K 59/873; B61D 25/00; B61L 15/009; H10K 59/126; H10K 59/131

(57) ABSTRACT

An insulated glass unit comprises a first tempered glass and a second tempered glass, which are disposed to face each other, a transparent OLED module provided between the first tempered glass and the second tempered glass, including a transparent OLED panel for displaying an image and a source printed circuit board (PCB) provided with a driving circuit for driving the transparent OLED panel, a spacer provided between an edge of the first tempered glass and an edge of the second tempered glass to form a space between the first tempered glass and the second tempered glass, and a cable having one end electrically connected to the source PCB and the other end exposed to the outside by passing through the spacer.

### CROSS-REFERENCE TO RELATED APPLICATION

This application claims the priority of the Korean Patent Application No. 10-2022-0108592 filed on Aug. 29, 2022, which is hereby incorporated by reference in its entirety.

### BACKGROUND

### Field of the Disclosure

The present disclosure relates to an insulated class unit with a transparent OLED panel and a mobility system including the same.

### Description of the Background

An insulated glass unit having an air layer inside a double-layered glass is applied, for insulation and soundproof, to a window of a train. Recently, studies for applying a display into an insulated glass unit to provide image information to passengers on a train through a window are actively ongoing.

Conventional displays such as a liquid crystal display (LCD), a plasma display panel (PDP), a quantum dot light emitting display (QLED) and an organic light emitting display (OLED) may disturb a passenger's view when they are applied to train windows. As a result, the passenger on the train may have a safety problem such as difficulty in making sure of visibility in emergency situations, thereby failing to respond to the emergency situations appropriately.

Also, since the train is exposed to the outdoors for a long time, there is another problem that if the display is applied to the window, the display is exposed to UV for a long time and thus is likely to cause a driving defect.

In addition, since the train shakes as it moves, if the display is applied to the window, the display may collide with the glass inside the window, whereby a problem occurs in that the display may be damaged.

### SUMMARY

The present disclosure has been made in view of the above problems and the present disclosure is to provide an insulated glass unit equipped with a transparent OLED panel capable of providing image information to mobility passengers and a mobility system including the same.

The present disclosure is also to provide an insulated glass unit equipped with a transparent OLED panel capable of making sure of a mobility passenger's view and a mobility system including the same.

The present disclosure is also to provide an insulated glass unit equipped with a transparent OLED panel capable of reducing driving defects caused by UV and a mobility system including the same.

In addition, the present disclosure is to provide an insulated glass unit equipped with a transparent OLED panel capable of preventing moisture inflow and a mobility system including the same.

Further, the present disclosure is to provide an insulated glass unit equipped with a transparent OLED panel capable of preventing internal parts from being damaged by shaking of a mobility and a mobility system including the same.

In addition to the present disclosure as mentioned above, additional features of the present disclosure will be clearly understood by those skilled in the art from the following description of the present disclosure.

In accordance with an aspect of the present disclosure, an insulated glass unit includes a first tempered glass and a second tempered glass, which are disposed to face each other, a transparent OLED module provided between the first tempered glass and the second tempered glass, including a transparent OLED panel for displaying an image and a source printed circuit board (PCB) provided with a driving circuit for driving the transparent OLED panel, a spacer provided between an edge of the first tempered glass and an edge of the second tempered glass to form a space between the first tempered glass and the second tempered glass, and a cable having one end electrically connected to the source PCB and the other end exposed to the outside by passing through the spacer.

In accordance with another aspect of the present disclosure, a mobility system includes an insulated glass unit (IGU) installed in at least one window of a mobility and provided with a transparent OLED module between a first tempered glass and a second tempered glass, which are disposed to face each other, an OLED controller connected to the transparent OLED module provided in the IGU, through a cable, and a communication controller receiving image data and streaming the received image data to the OLED controller via a switch hub.

It is to be understood that both the foregoing general description and the following detailed description are exemplary and explanatory and are intended to provide further explanation of the disclosure as claimed.

### BRIEF DESCRIPTION OF THE DRAWINGS

The above and other objects, features and other advantages of the present disclosure will be more clearly understood from the following detailed description taken in conjunction with the accompanying drawings, in which:

FIG. 1 is a schematic perspective view illustrating an insulated glass unit according to one aspect of the present disclosure;

FIG. 2 is a plan view illustrating a transmissive window area, a printing area and a bezel area of an insulated glass unit according to one aspect of the present disclosure;

FIG. 3 is a view illustrating an example of a pixel provided in a transparent OLED panel shown in FIG. 2;

FIG. 4 is a cross-sectional view illustrating an example of line I-I′ of FIG. 2;

FIG. 5 is a cross-sectional view illustrating an example of a first spacer and a second spacer;

FIG. 6 is a cross-sectional view illustrating an example of a configuration of a first spacer;

FIG. 7 is a plan view illustrating an example of a first adhesive structure disposed on one surface of a source PCB;

FIG. 8 is a plan view illustrating an example of a second adhesive structure disposed on the other surface of a source PCB;

FIG. 9 is a cross-sectional view illustrating a first adhesive structure, a second adhesive structure and a heat emission structure;

FIG. 10 is a block view illustrating a mobility system according to one aspect of the present disclosure;

FIG. 11 is a side view and a plan view schematically illustrating an example in which an IGU, an OLED controller, a switch hub and a communication controller are disposed in a mobility;

FIG. 12 is a plan view schematically illustrating an example of image data transmission among an IGU, an OLED controller, a switch hub and a communication controller in a mobility;

FIG. 13 is a plan view schematically illustrating an example of power supply of an IGU, an OLED controller, a switch hub and a communication controller in a mobility; and

FIG. 14 is a view illustrating an example in which an IGU according to one aspect of the present disclosure is applied to a train.

### DETAILED DESCRIPTION

Advantages and features of the present disclosure, and implementation methods thereof will be clarified through following aspects described with reference to the accompanying drawings. The present disclosure may, however, be embodied in different forms and should not be construed as limited to the aspects set forth herein. Rather, these aspects are provided so that this disclosure will be thorough and complete, and will fully convey the scope of the present disclosure to those skilled in the art.

A shape, a size, dimensions (e.g., length, width, height, thickness, radius, diameter, area, etc.), a ratio, an angle, and a number of elements disclosed in the drawings for describing aspects of the present disclosure are merely an example, and thus, the present disclosure is not limited to the illustrated details.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Like reference numerals refer to like elements throughout the specification. In the following description, when the detailed description of the relevant known function or configuration is determined to unnecessarily obscure the important point of the present disclosure, the detailed description will be omitted. In a case where ‘comprise,’ ‘have,’ and ‘include’ described in the present specification are used, another part may be added unless ‘only˜’ is used. The terms of a singular form may include plural forms unless referred to the contrary.

In construing an element, the element is construed as including an error range although there is no explicit description.

In describing a position relationship, for example, when the position relationship is described as ‘upon˜,’ ‘above˜,’ ‘below˜,’ and ‘next to˜,’ one or more portions may be arranged between two other portions unless ‘just’ or ‘direct’ is used.

It will be understood that, although the terms “first,” “second,” etc., may be used herein to describe various elements, these elements should not be limited by these terms. These terms are only used to distinguish one element from another. For example, a first element could be termed a second element, and, similarly, a second element could be termed a first element, without departing from the scope of the present disclosure.

In describing elements of the present disclosure, the terms “first,” “second,” etc., may be used. These terms are intended to identify the corresponding elements from the other elements, and basis, order, or number of the corresponding elements are not limited by these terms. The expression that an element is “connected” or “coupled” to another element should be understood that the element may directly be connected or coupled to another element but may directly be connected or coupled to another element unless specially mentioned, or a third element may be interposed between the corresponding elements.

Features of various aspects of the present disclosure may be partially or overall coupled to or combined with each other, and may be variously inter-operated with each other and driven technically as those skilled in the art may sufficiently understand. The aspects of the present disclosure may be carried out independently from each other, or may be carried out together in co-dependent relationship.

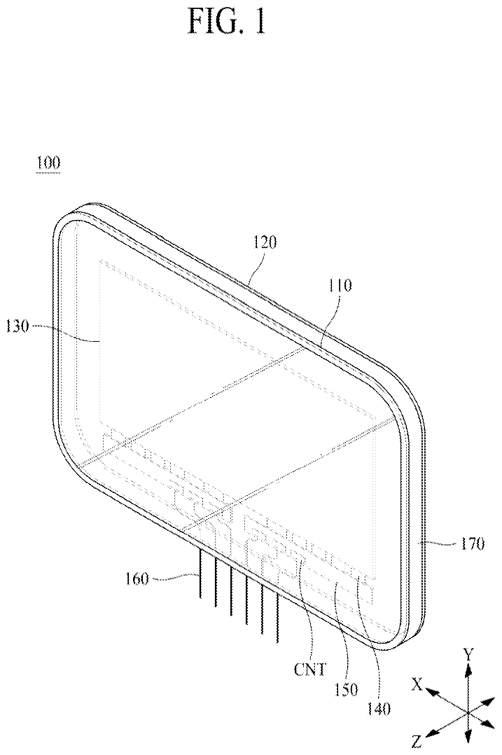

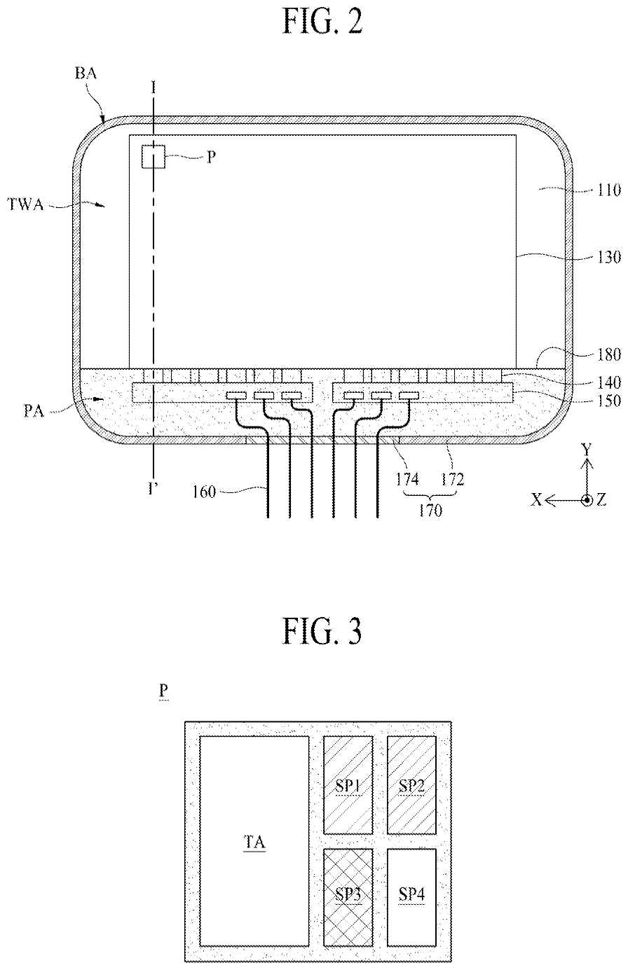

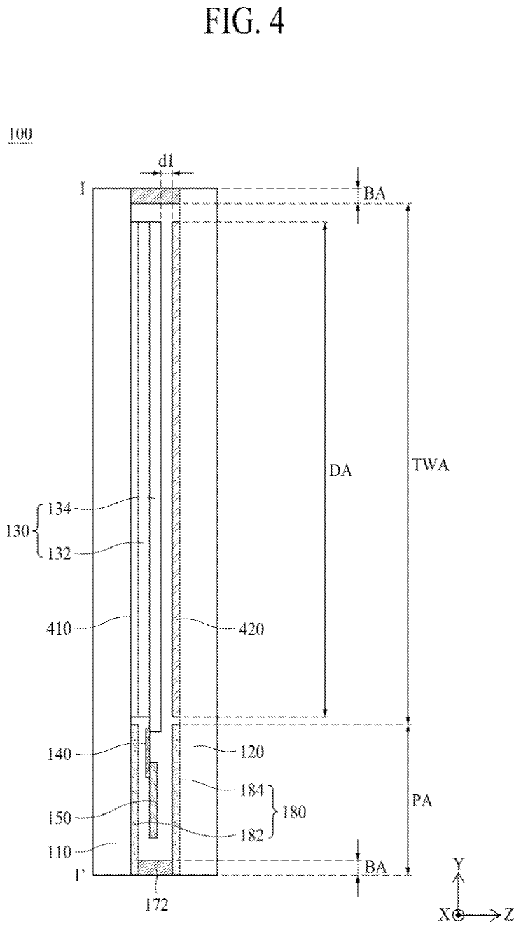

FIG. 1 is a schematic perspective view illustrating an insulated glass unit according to one aspect of the present disclosure, and FIG. 2 is a plan view illustrating a transmissive window area, a printing area and a bezel area of an insulated glass unit according to one aspect of the present disclosure. FIG. 3 is a view illustrating an example of a pixel provided in a transparent OLED panel shown in FIG. 2, and FIG. 4 is a cross-sectional view illustrating an example of line I-I′ of FIG. 2.

Referring to FIGS. 1 to 4, an insulated glass unit (IGU) 100 according to one aspect of the present disclosure may be divided into a bezel area BA, a transmissive window area TWA and a printing area PA.

The bezel area BA may correspond to an edge of the IGU 100. The printing area PA is an area in which light is not transmitted, and may be disposed at an upper end or a lower end of the transmissive window area TWA. The transmissive window area TWA is an area through which light passes so that a user may view an object or a background, which is positioned to be opposite to the user.

In detail, the IGU 100 includes a first tempered glass 110, a second tempered glass 120, a transparent OLED module, a cable 160 and a spacer 170.

The first tempered glass 110 and the second tempered glass 120 are disposed to face each other. The first tempered glass 110 may be disposed toward the user, and the second tempered glass 120 may be disposed to face an opposite side of the user. For example, when the IGU 100 is installed in the mobility, the first tempered glass 110 may be disposed toward an inner space of the mobility on which the user is on board, and the second tempered glass 120 may be disposed toward an outer space of the mobility.

The first tempered glass 110 and the second tempered glass 120 may transmit light. Light emitted from the transparent OLED module passes through the first tempered glass 110 so that the user may view image information. Also, as external light passes through the first tempered glass 110 and the second tempered glass 120, the user may view the outside.

The transparent OLED module is provided between the first tempered glass 110 and the second tempered glass 120, and outputs an image based on image information input from the outside. The transparent OLED module includes a transparent OLED panel 130, a chip-on-film (COF) 140 and a source printed circuit board (PCB) 150.

The transparent OLED panel 130 includes a display area DA in which a plurality of pixels P are provided to display an image. Each of the pixels P may include a first subpixel SP1, a second subpixel SP2, a third subpixel SP3 and a fourth subpixel SP4. Each of the first subpixel SP1, the second subpixel SP2, the third subpixel SP3 and the fourth subpixel SP4 may include an OLED element between the first substrate 132 and the second substrate 134 to emit light of a predetermined color. The first subpixel SP1 may include a first light emission area for emitting light of a first color, and the second subpixel SP2 may include a second light emission area for emitting light of a second color. The third subpixel SP3 may include a third light emission area for emitting light of a third color, and the fourth subpixel SP4 may include a fourth light emission area for emitting light of a fourth color.

Meanwhile, as shown in FIG. 3, the transparent OLED panel 130 may be provided with a transmissive area TA between the pixels P. In this case, the transmissive area TA may be an area through which most of light incident from the outside passes. The transparent OLED panel 130 is able to view an object or a background, which is positioned on a rear surface of the IGU 100, due to transmissive areas TA.

The transparent OLED panel 130 may be disposed between the first tempered glass 110 and the second tempered glass 120. In detail, as shown in FIG. 4, the transparent OLED panel 130 may be fixed to one surface of the first tempered glass 110 by a first adhesive layer 410 through a direct bonding process. In this case, the first adhesive layer 410 may be an optical adhesive layer. The IGU 100 may attach the transparent OLED panel 130 to the inside by optical bonding without degradation of resolution of the transparent OLED panel 130.

In addition, in the IGU 100 according to one aspect of the present disclosure, the transparent OLED panel 130 may be fixed to the first tempered glass 110 so that the user may stably view image information even in a moving space such as the mobility.

The transparent OLED panel 130 may emit light toward the first tempered glass 110 disposed on a front surface of the IGU 100. In this case, the light emitted from the transparent OLED panel 130 may be transferred to the user by passing through the first tempered glass 110.

In addition, the transparent OLED panel 130 passes external light incident on the rear surface of the IGU 100 through the transmissive area TA, and light passing through the transparent OLED panel 130 may be transferred to the user by passing through the first tempered glass 110. Therefore, an area in which the transparent OLED panel 130 is disposed may correspond to the transmissive window area TWA. That is, the transparent OLED panel 130 may at least partially overlap with the transmissive window area TWA. The transparent OLED panel 130 may have the same size as that of the transmissive window area TWA or may have a size smaller than that of the transmissive window area TWA.

The IGU 100 according to one aspect of the present disclosure includes a transparent OLED panel 130 which displays an image and at the same time transmits external light. Therefore, the user may receive image information through the IGU 100 and at the same time make sure of a field of view, thereby making sure of safety in case of an emergency situation.

The COF 140 may be disposed in the printing area PA between the first tempered glass 110 and the second tempered glass 120. The COF 140 electrically connects the transparent OLED panel 130 with the source PCB 150. In detail, the COF 140 may be provided with lines for connecting pads formed on the transparent OLED panel 130 with lines of the source PCB 150. The COF 140 is attached on the pads by using an anisotropic conducting film, whereby the pads may be connected to the lines of the COF 140.

The COF 140 may include a drive IC. The drive IC converts digital image data into analog data voltages in accordance with a source control signal and supply the analog data voltages to the transparent OLED panel 130. The COF 140 may further include lines for connecting the pads formed on the transparent OLED panel 130 with a drive IC.

The source PCB 150 may be disposed in the printing area PA between the first tempered glass 110 and the second tempered glass 120. The source PCB 150 may be connected to each subpixel of the transparent OLED panel 130 through the COF 140 to supply an image signal and a control signal to each subpixel. A plurality of driving circuits for driving the transparent OLED panel 130 may be packaged on the source PCB 150. The source PCB 150 may include at least one of an image processing circuit, a timing control circuit, a data driving circuit or a scan driving circuit.

The image processing circuit may output a data signal and a timing signal, which are image information supplied from the outside.

The timing control circuit may receive the data signal and the timing signal from the image processing circuit. The timing control circuit may output a scan timing control signal for controlling an operation timing of the scan driving circuit and a data timing control signal for controlling an operation timing of the data driving circuit, based on the timing signal.

The data driving circuit may convert the data signal supplied from the timing control circuit in response to the data timing control signal supplied from the timing control circuit and output the converted data signal. The scan driving circuit may output the scan signal in response to the scan timing control signal supplied from the timing control circuit.

The transparent OLED panel 130 may display an image in response to the data signal and the scan signal, which are supplied from the data driving circuit and the scan driving circuit.

The IGU 100 according to one aspect of the present disclosure may further include a UV light shielding film 420 as shown in FIG. 4.

The UV light shielding film 420 may be provided on one surface of the second tempered glass 120. In detail, the UV light shielding film 420 may be provided on one surface of the second tempered glass 120, which faces the transparent OLED panel 130. At this time, the transparent OLED panel 130 does not emit light toward one surface of the second tempered glass 120, and may emit light toward the first tempered glass 110. That is, the UV light shielding film 420 may be disposed on one surface of the second tempered glass 120 disposed in a direction opposite to the direction in which the light emitted from the transparent OLED panel 130 moves.

The UV light shielding film 420 may be disposed to overlap with at least a portion of the transparent OLED panel 130, thereby preventing UV light incident on the other surface of the second tempered glass 120 from the outside from moving to the transparent OLED panel 130. When the IGU 100 is applied to a means, which moves outdoors, such as a mobility, the transparent OLED panel 130 provided inside the IGU 100 may be exposed to UV light for a long time rather than an OLED panel disposed indoors. For this reason, a driving defect may occur. In particular, a larger amount of UV light may be incident on the second tempered glass 120 disposed toward the outer space of the mobility than the first tempered glass 110 disposed toward the inner space of the mobility.

Therefore, the IGU 100 according to one aspect of the present disclosure may include a UV light shielding film 420 on one surface of the second tempered glass 120, so that the intensity or amount of the UV light incident on the transparent OLED panel 130 may be reduced. Therefore, the IGU 100 according to one aspect of the present disclosure may reduce the possibility of driving defects due to exposure of the transparent OLED panel 130 to the UV light for a long time, thereby improving reliability.

In addition, the IGU 100 according to one aspect of the present disclosure may include a UV light shielding film 420 therein, so that the UV light shielding film 420 may be prevented from being contaminated or damaged by external factors.

Meanwhile, the UV light shielding film 420 may be spaced apart from the transparent OLED panel 130 as much as a predetermined distance d1 to form a gap space. Alternatively, when the UV light shielding film 420 is directly formed on the transparent OLED panel 130, a portion of the UV light passing through the UV light shielding film 420 among the UV light incident from the outside is directly incident on the transparent OLED panel 130.

However, when a gap space is formed between the UV light shielding film 420 and the transparent OLED panel 130 as in the present disclosure, a portion of the UV light passing through the UV light shielding film 420 among the UV light incident from the outside may be diffusely reflected in the gap space. Therefore, a portion of the UV light passing through the UV light shielding film 420, which is directly incident on the transparent OLED panel 130, may be reduced due to diffused reflection. Therefore, the IGU 100 according to one aspect of the present disclosure may form a gap space between the UV light shielding film 420 and the transparent OLED panel 130, thereby further improving a UV light shielding effect.

The IGU 100 according to one aspect of the present disclosure may further include a printing layer 180 as shown in FIG. 4.

The printing layer 180 may be provided to overlap with at least a portion of the cable 160, the COF 140 and the source PCB 150, so that at least a portion of the cable 160, the COF 140 and the source PCB 150 may be covered so as not to be seen from the outside. In detail, the printing layer 180 may include a first printing layer 182 and a second printing layer 184.

The first printing layer 182 may be provided on one surface of the first tempered glass 110. The first printing layer 182 may be provided to overlap with at least a portion of the cable 160, the COF 140 and the source PCB 150, so that at least a portion of the cable 160, the COF 140 and the source PCB 150 may be covered from the front surface of the IGU 100 so as not to be exposed to the user.

The second printing layer 184 may be provided on one surface of the second tempered glass 120, and may not overlap with the UV light shielding film 420. The second printing layer 184 may be provided to overlap with at least a portion of the cable 160, the COF 140 and the source PCB 150 so that at least a portion of the cable 160, the COF 140 and the source PCB 150 may be covered from the rear surface of the IGU 100 so as not to be exposed to the user.

In the IGU 100 according to one aspect of the present disclosure, at least a portion of the cable 160, the COF 140 and the source PCB 150 may be disposed in the printing area PA, so that at least a portion of the cable 160, the COF 140 and the source PCB 150 may not be exposed to the user, thereby improving an aesthetic sense of an external appearance.

Also, in the IGU 100 according to one aspect of the present disclosure, the UV light incident from the outside may be prevented from moving to at least a portion of the cable 160, the COF 140 and the source PCB 150 by the printing layer 180. Therefore, the IGU 100 according to one aspect of the present disclosure may protect the circuit and parts, which are provided in the COF 140 and the source PCB 150, from the UV light.

The spacer 170 may be provided along the edge between the first tempered glass 110 and the second tempered glass 130. An area in which the spacer 170 is formed may correspond to the bezel area BA. The spacer 170 spaces the first tempered glass 110 and the second tempered glass 130 apart from each other, and forms a space in which the transparent OLED viewing module will be disposed between the first tempered glass 110 and the second tempered glass 130.

Also, the spacer 170 may fix the first tempered glass 110 and the second tempered glass 130 to each other and separate the inner space and the outer space of the IGU 100 from each other. The inner space of the IGU 100 may be sealed from the outer space by the first tempered glass 110, the second tempered glass 130 and the spacer 170.

The cable 160 electrically connects the source PCB 150 with an external separate controller. In detail, one end of the cable 160 may be electrically connected to a connector CNT provided in the source PCB 150, and the other end of the cable 160 may be exposed to the outside by passing through the spacer 170. The other end of the cable 160 may be electrically connected to the external separate controller. Image information output from the separate external controller may be transferred to the circuit provided in the source PCB 150 through the cable 160.

Also, the cable 160 may be connected to an external power source to supply the power source to the transparent OLED module.

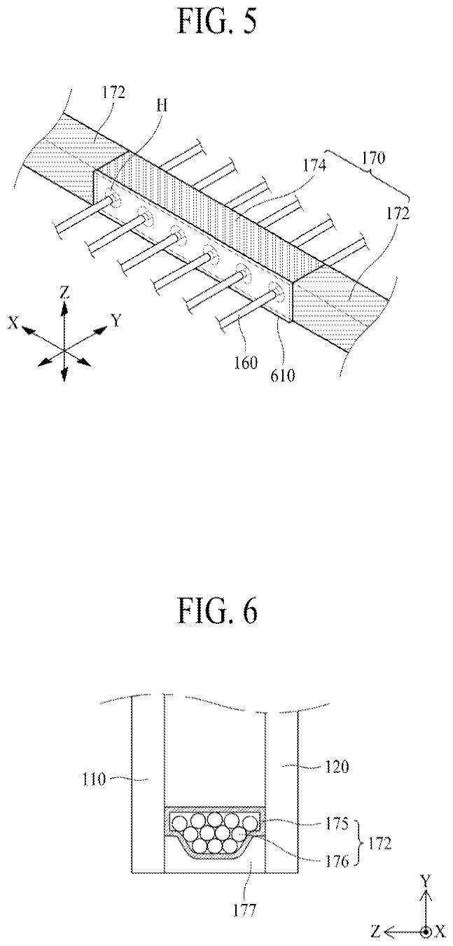

In the IGU 100 according to one aspect of the present disclosure, the cable 160 may pass through the spacer 170 to expose a portion of the cable 160 to the outside. The IGU 100 according to one aspect of the present disclosure includes the spacer 170 capable of maintaining a humidity sealing effect with respect to the internal space even when the cable 160 is exposed to the outside. Hereinafter, the spacer 170 according to the present disclosure will be described in detail with reference to FIGS. 5 and 6.

FIG. 5 is a cross-sectional view illustrating an example of a first spacer and a second spacer, and FIG. 6 is a cross-sectional view illustrating an example of a configuration of the first spacer.

Referring to FIGS. 2, 5 and 6, the spacer 170 according to one aspect of the present disclosure includes a first spacer 172 and a second spacer 174.

The first spacer 172 is provided along the edge between the first tempered glass 110 and the second tempered glass 120, and has an open area on at least one side. The open area may correspond to an area through which the cable 160 passes. Since one end of the cable 160 is connected to the source PCB 150, the first spacer 172 may have an open area on a side where the source PCB 150 is disposed.

The first spacer 172 may include a spacer bar 175, a desiccant 176 and an adhesive 177 as shown in FIG. 6.

The spacer bar 175 may be provided along the edge between the first tempered glass 110 and the second tempered glass 120. The spacer bar 175 may form a space by spacing the first tempered glass 110 and the second tempered glass 120 apart from each other.

The desiccant 176 may be disposed inside the spacer bar 175. The desiccant 176 may maintain the air in the inner space between the first tempered glass 110 and the second tempered glass 120 in a dry state.

The adhesive 177 may be disposed outside the spacer bar 175. The adhesive 177 may fix the first tempered glass 110, the second tempered glass 120 and the spacer bar 175 such that a gap between the first tempered glass 110 and the second tempered glass 120 is not widened.

Also, the adhesive 177 may fix the first tempered glass 110, the second tempered glass 120 and the spacer bar 175 so that the gap between the first tempered glass 110 and the second tempered glass 120 is not widened. The adhesive 177 may be coated on the gap among the first tempered glass 110 and the second tempered glass 120 and the spacer bar 175 to prevent moisture and gas leakage. In addition, the adhesive 177 may prevent external moisture from flowing into the inner space of the IGU 100.

The second spacer 174 may be provided with a plurality of holes H, and may be disposed in an open area of the first spacer 172. The cable 160 may pass through at least one of the plurality of holes H provided in the second spacer 174 to expose its other end to the outside.

The second spacer 174 is formed as an independent component distinguished from the first spacer 172, and thus may be detachably provided.

In the IGU 100 according to one aspect of the present disclosure, the other end of the cable 160 may be exposed to the outside through the plurality of holes H provided in the second spacer 174, so that the IGU 100 may be easily sealed without increase in its thickness.

One of methods of exposing the cable 160 to the outside may consider that the cable 160 passes through a gap between the first tempered glass 110 or the second tempered glass 120 and the spacer 170. However, in this method, the thickness of the IGU 100 may be increased as the gap between the first tempered glass 110 or the second tempered glass 120 and the spacer 170 is widened due to the thickness of the cable 160. In addition, as the plurality of cables 160 are disposed between the first tempered glass 110 or the second tempered glass 120 and the spacer 170, a large gap may occur between the first tempered glass 110 or the second tempered glass 120 and the spacer 170. In this case, it is not easy to seal the IGU 100, and external moisture may be introduced through the cable 160. Dew condensation may occur due to a temperature difference between the inner space and the outer space, thereby disturbing a user's field of view. In addition, an insulation effect of the IGU 100 may be reduced.

In addition, another one of the methods of exposing the cable 160 to the outside may consider that the COF 140 and the source PCB 150 are pulled out to the outside. However, in this method, the COF 140 may be disposed at a boundary between the inner space and the outer space of the IGU 100. In this case, an impact may be applied to the COF 140 due to movement of the mobility. The COF 140 may be made in the form of a thin film and thus may be easily torn or damaged. Furthermore, lines provided in the COF 140 may be broken, whereby image information or power source input from the outside may not be supplied to the transparent OLED panel 130. That is, the transparent OLED panel 130 may not operate normally.

Unlike the above-described method, in the IGU 100 according to one aspect of the present disclosure, an open area may be provided in the first spacer 172, and the second spacer 174 formed in an independent component from the first spacer 172 may be fitted into the open area of the first spacer 172. Also, in the IGU 100 according to one aspect of the present disclosure, a plurality of holes H through which the cable 160 may pass may be provided in the second spacer 174, so that the gap between the first tempered glass 110 or the second tempered glass 120 and the spacer 170 may be prevented from being widened due to the cable 160.

Also, the IGU 100 according to one aspect of the present disclosure may minimize a gap by allowing a diameter of the plurality of holes H of the second spacer 174 to have a minimum size to which the cable 160 may be inserted.

In addition, in the IGU 100 according to one aspect of the present disclosure, the cable 160 not the COF 140 made in the form of a thin film may be disposed at a boundary between the inner space and the outer space of the IGU 100. The cable 160 has a wire thicker than that of the COF 140 and its wire is coated with a coating layer. Therefore, in the IGU 100 according to one aspect of the present disclosure, even though the cable 160 is disposed at the boundary between the inner space and the outer space of the IGU 100, the cable 160, particularly, the electric wire may not be damaged due to movement of the mobility. That is, the IGU 100 according to one aspect of the present disclosure may stably supply image information or power source input from the outside to the transparent OLED panel 130.

In addition, in the IGU 100 according to one aspect of the present disclosure, since the second spacer 174 may be detachably provided, the cable 160, etc. may be easily repaired.

Meanwhile, the spacer 170 according to one aspect of the present disclosure may further include a sealing layer 610. The sealing layer 610 may be disposed outside the second spacer 174 to seal the plurality of holes H of the second spacer 174, through which the cable 160 passes. In the IGU 100 according to one aspect of the present disclosure, the sealing layer 610 may be formed, and thus a high sealing effect may be expected even though the cable 160 passes through the spacer 170.

Although not shown in detail, the IGU 100 according to one aspect of the present disclosure may further include an adhesive structure for fixing the source PCB 150. The COF 140 and the source PCB 150 may collide with the first tempered glass 110 and the second tempered glass 120 due to movement of the mobility, whereby the COF 140 and the source PCB 150 may be damaged. In this case, since no driving signal is not input to the transparent OLED panel 130, the transparent OLED panel 130 cannot display an image.

In the IGU 100 according to one aspect of the present disclosure, the source PCB 150 may be fixed to the first tempered glass 110 by using the adhesive structure, whereby the COF 140 and the source PCB 150 may be prevented from being damaged due to movement of the mobility.

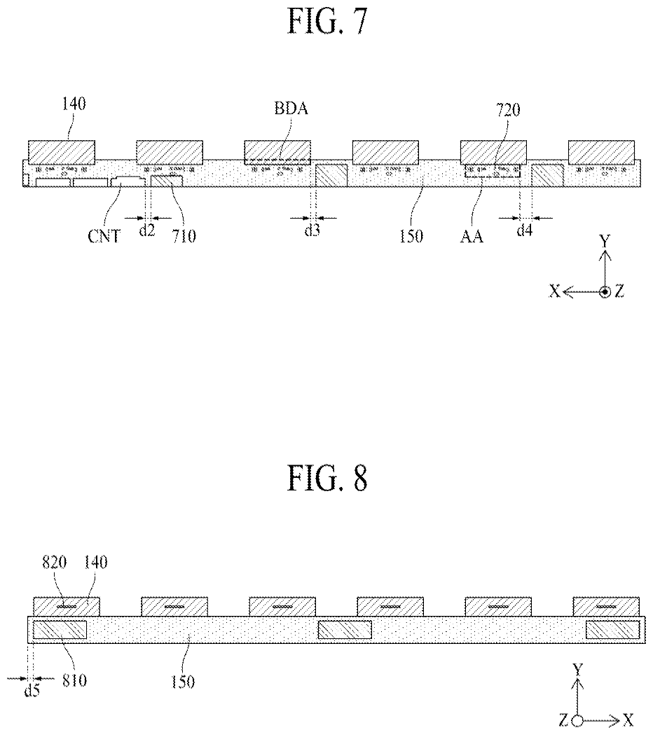

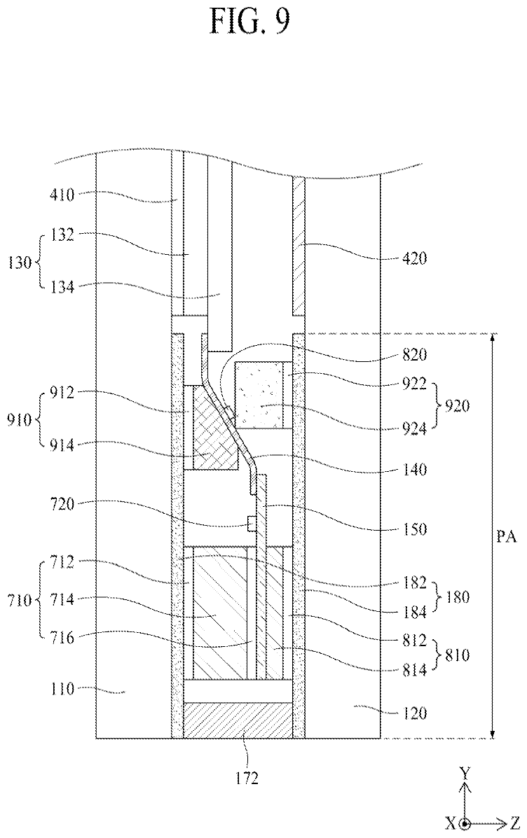

Hereinafter, the adhesive structure according to the present disclosure will be described in detail with reference to FIGS. 7 and 9.

FIG. 7 is a plan view illustrating an example of a first adhesive structure disposed on one surface of a source PCB, FIG. 8 is a plan view illustrating an example of a second adhesive structure disposed on the other surface of a source PCB, and FIG. 9 is a cross-sectional view illustrating a first adhesive structure, a second adhesive structure and a heat emission structure.

Referring to FIGS. 7 to 9, the IGU 100 according to one aspect of the present disclosure may further include a first adhesive structure 710 and a second adhesive structure 810.

The first adhesive structure 710 may be disposed between the first tempered glass 110 and the source PCB 150. One surface of the first adhesive structure 710, which faces the first tempered glass 110, may be adhered to the first tempered glass 110, and the other surface of the first adhesive structure 710, which faces the source PCB 150, may be adhered to the source PCB 150. The source PCB 150 may be spaced apart from the first tempered glass 110 by the first adhesive structure 710 and fixed to the first tempered glass 110.

The first adhesive structure 710 may be a double-sided foam tape that includes a first adhesive layer 712, a foam 714 and a second adhesive layer 716. In one aspect, the foam 714 of the first adhesive structure 710 may be a polyolefin foam.

The IGU 100 according to one aspect of the present disclosure may include a first adhesive structure 710 between the first tempered glass 110 and the source PCB 150, thereby preventing circuits provided in the source PCB 150 from colliding with the first tempered glass 110 due to movement of the mobility.

A plurality of active elements 270, which includes a plurality of connectors CNT for connection with the cable 160 and a transistor, may be provided on one surface of the source PCB 150 as shown in FIG. 7, and a bonding area BDA with the COF 140 may be provided on one side of the source PCB 150. In this case, one surface of the source PCB 150 is a front surface, and may correspond to a surface facing the first tempered glass 110.

The first adhesive structure 710 may be disposed so as not to overlap with the plurality of connectors CNT to be attached to one surface of the source PCB 150. That is, the first adhesive structure 710 may be spaced apart from each of the plurality of connectors CNT at a predetermined distance d2. In the IGU 100 according to one aspect of the present disclosure, the first adhesive structure 710 and the connector CNT may be disposed to be spaced apart from each other, whereby it is possible to prevent the first adhesive structure 710 from giving any impact to the connector CNT and the cable 160 connected to the connector CNT due to vibration. Therefore, the IGU 100 according to one aspect of the present disclosure may prevent the cable 160 from being detached from the connector CNT by vibration.

Also, the first adhesive structure 710 may be disposed so as not to overlap with the bonding area BDA with the COF 140 to be attached to one surface of the source PCB 150. That is, the first adhesive structure 710 may be spaced apart from the bonding area BDA with the COF 140 at a predetermined distance d3. In the IGU 100 according to one aspect of the present disclosure, the first adhesive structure 710 and the bonding area BDA may be disposed to be spaced apart from each other, whereby it is possible to prevent the first adhesive structure 710 from giving any impact to the bonded COF 140 due to vibration. Therefore, the IGU 100 according to one aspect of the present disclosure may prevent a bonding defect from occurring in the COF 140 due to vibration.

Also, the first adhesive structure 710 may be disposed so as not to overlap with an active element area AA provided with a plurality of active elements 270 to be attached to one surface of the source PCB 150. That is, the first adhesive structure 710 may be spaced apart from the active element area AA at a predetermined distance d4. In the IGU 100 according to one aspect of the present disclosure, the first adhesive structure 710 may be spaced apart from the active element area AA, so that heat generated from the plurality of active elements 270 may be prevented from being transferred to the first adhesive structure 710.

When the first adhesive structure 710 is in contact with the plurality of active elements 270, the heat generated from the plurality of active elements 270 may be transferred to the first adhesive structure 710. In this case, an adhesive force of the first and second adhesive layers 712 and 716 of the first adhesive structure 710 may be weakened by heat. As a result, the first adhesive structure 710 may be separated from the first tempered glass 110 or the source PCB 150.

In the IGU 100 according to one aspect of the present disclosure, the first adhesive structure 710 and the active element area AA may be disposed to be spaced apart from each other, so that an adhesive force of the first adhesive structure 710 may be prevented from being weakened due to the heat generated from the active elements 270.

The second adhesive structure 810 may be disposed between the second tempered glass 120 and the source PCB 150. One surface of the second adhesive structure 810, which faces the second tempered glass 120, may be adhered to the second tempered glass 120.

The second adhesive structure 810 may be disposed to face the other surface of the source PCB 150. In this case, the other surface of the source PCB 150 is a rear surface, and may correspond to a surface facing the second tempered glass 120.

The second adhesive structure 810 may overlap with at least a portion of the first adhesive structure 710 with the source PCB deck 150 interposed therebetween, or not. Unlike one surface of the source PCB 150 to which the first adhesive structure 710 is attached, the other surface of the source PCB 150 may not include a plurality of connectors CNT, a plurality of active elements 270, and a bonding area BDA with the COF 140. Therefore, the second adhesive structure 810 may be freely disposed without considering components provided on the other surface of the source PCB 150. Since the second adhesive structure 810 does not necessarily overlap with the first adhesive structure 710, at least a portion of the second adhesive structure 810 may overlap with the first adhesive structure 710 with the source PCB 150 interposed therebetween, or not. The second adhesive structure 810 may have a structure different from that of the first adhesive structure 710 attached to one surface of the source PCB 150. The first adhesive structure 710 may be a double-sided foam tape provided with an adhesive layer on both surfaces thereof, whereas the second adhesive structure 810 may be a single-sided foam tape provided with a first adhesive layer 812 and a foam 814. In one aspect, the foam 814 of the second adhesive structure 810 may be a polyurethane foam.

Also, the second adhesive structure 810 may be different in thickness from the first adhesive structure 710. In one aspect, the first adhesive structure 710 may be thicker than the second adhesive structure 810. For example, the first adhesive structure 710 may have a thickness close to approximately 8 times to 9 times the thickness of the second adhesive structure 810.

The IGU 100 according to one aspect of the present disclosure may include a second adhesive structure 810 between the second tempered glass 120 and the source PCB 150, thereby preventing the rear surface of the source PCB 150 from colliding with the second tempered glass 120. Therefore, the IGU 100 according to one aspect of the present disclosure may prevent the source PCB 150 from being damaged, and may prevent noise from being generated when the source PCB 150 collides with the second tempered glass 120.

Meanwhile, the second adhesive structure 810 may be disposed to be spaced apart from the source PCB 150 based on the edge of the source PCB 150 at a predetermined distance d5. In the IGU 100 according to one aspect of the present disclosure, the second adhesive structure 810 may be disposed to be spaced apart from the source PCB 150 based on the edge of the source PCB 150, so that the second adhesive structure 810 may be prevented from being detached by vibration.

Meanwhile, the IGU 100 according to one aspect of the present disclosure may further include a heat emission structure 910 as shown in FIG. 9.

The heat emission structure 910 may be disposed between the first tempered glass 110 and the COF 140. The heat emission structure 910 may be fixed to one surface of the first tempered glass 110 by an adhesive layer 912. In addition, the heat emission structure 910 may lower heat generated from the COF 140 through the heat emission layer 914 including a metal material.

In more detail, the COF 140 may be provided with a drive IC 820 from which heat is generated. Since the IGU 100 has a structure in which the inner space is sealed, a structure for lowering heat generated from the drive IC 820 may be required. If not so, the IGU 100 may be overheated due to the heat generated in the inner space, whereby the active elements 720 provided in the transparent OLED panel 130, the COF 140 and the source PCB 150 may be damaged.

The IGU 100 according to one aspect of the present disclosure may include a heat emission structure 910 to lower the heat generated from the drive IC 820. In the IGU 100 according to one aspect of the present disclosure, an inclined surface having a gradient similar to that of the COF 140 is provided in the heat emission layer 914 of the heat emission structure 910, and the COF 140 comes into contact with the inclined surface of the heat emission layer 914, whereby heat generated from the drive IC 820 may be lowered.

The IGU 100 according to one aspect of the present disclosure may further include a pressing structure 920 as shown in FIG. 9.

The pressing structure 920 may be disposed between the second tempered glass 120 and the COF 140. The pressing structure 920 may be fixed to one surface of the second tempered glass 120 by an adhesive layer 922. In addition, the pressing structure 920 may press the COF 140 toward the heat emission structure 910 by using a foam pad 924 having a predetermined thickness.

The pressing structure 920 may be disposed to be in contact with the drive IC 820 provided in the COF 140. In this case, in the IGU 100 according to one aspect of the present disclosure, the pressing structure 920 may press the drive IC 820 toward the heat emission structure 910 to make sure of contact between the drive IC 820 and the lines provided in the COF 140.

Also, in the IGU 100 according to one aspect of the present disclosure, the pressing structure 920 may be formed of a foam pad 924 capable of absorbing shock, whereby the COF 140 may be prevented from being damaged due to vibration.

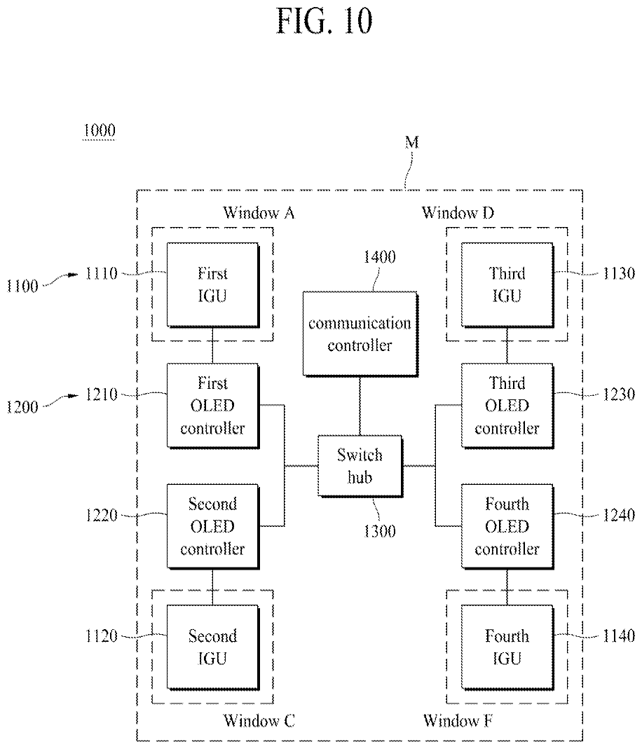

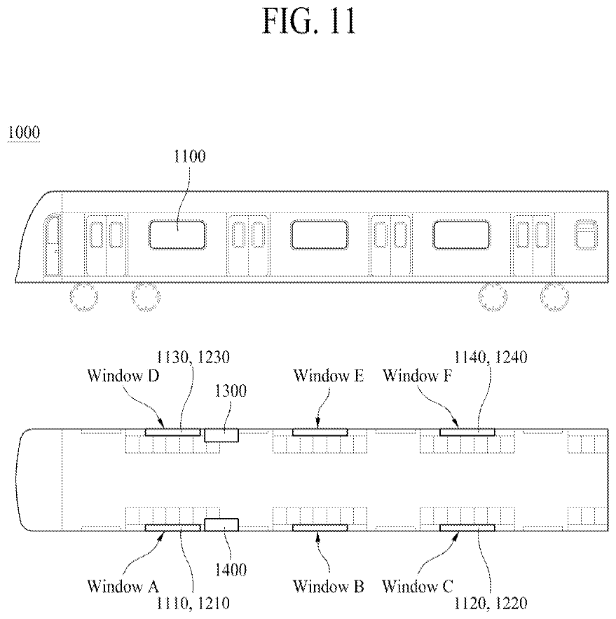

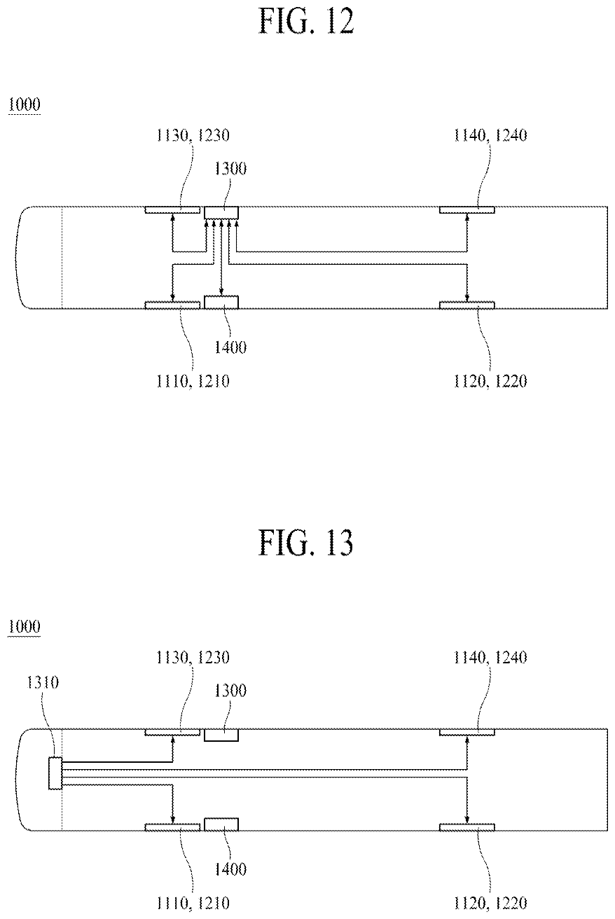

FIG. 10 is a block view illustrating a mobility system according to one aspect of the present disclosure, FIG. 11 is a side view and a plan view schematically illustrating an example in which an IGU, an OLED controller, a switch hub and a communication controller are disposed in a mobility, and FIG. 12 is a plan view schematically illustrating an example of image data transmission among an IGU, an OLED controller, a switch hub and a communication controller in a mobility. FIG. 13 is a plan view schematically illustrating an example of power supply of an IGU, an OLED controller, a switch hub and a communication controller in a mobility.

A mobility system 1000 according to one aspect of the present disclosure controls an IGU 1100 installed in a mobility M. In detail, a mobility system 1000 includes an IGU 1100, an OLED controller 1200, a switch hub 1300 and a communication controller 1400 as shown in FIG. 10.

The IGU 1100 is installed in a window provided in mobility M. In this case, the mobility M is a moving means for providing mobility of a person and an object, and may include a train, a subway, a vehicle and the like. Hereinafter, for convenience of description, the mobility M is described as being a train, but the present disclosure is not limited thereto.

The mobility M may include a plurality of windows. For example, the mobility M may include six windows as shown in FIG. 11. In detail, the mobility M may be disposed so that three windows Window A, Window B and Window C may be spaced apart from one another on a left side of the mobility M toward a moving direction at a predetermined interval. In addition, the mobility M may be disposed so that three windows Window D, Window E and Window F may be spaced apart from one another on a right side of the mobility M toward the moving direction at a predetermined interval.

The IGU 1100 may be installed on at least one of the plurality of windows Window A, Window B, Window C, Window D, Window E and Window F. For example, the mobility M may be installed on four windows Window A, Window C, Window D and Window F of six windows Window A, Window B, Window C, Window D, Window E and Window F as shown in FIG. 11. The IGU 1100 may be installed on two windows Window A and Window C except a central window on the left side of the mobility M. The IGU 1100 may be installed on two windows Window D and Window F except the central window on the right side of the mobility M.

That is, a plurality of IGUs 1100 may be provided in the mobility M. In FIG. 10, a first IGU 1110, a second IGU 1120, a third IGU 1130 and a fourth IGU 1140 are shown as being provided in the mobility M, but the present disclosure is not limited thereto. Four or more IGUs 1100 or IGUs less than four may be provided in one mobility M.

However, for convenience of description, it is assumed that four IGUs 1110, 1120, 1130 and 1140 are provided in one mobility M. When the mobility M is a train, one mobility M may mean one vehicle constituting a train.

Each of the first to fourth IGUs 1110, 1120, 1130 and 1140 may include a transparent OLED module provided between a first tempered glass and a second tempered glass, which are disposed to face each other. Since the IGUs 1110, 1120, 1130 and 1140 shown in FIGS. 10 to 14 are substantially the same as the IGU 100 described with reference to FIGS. 1 to 9, a detailed description of the configuration of the IGUs 1110, 1120, 1130 and 1140 will be omitted.

The first to fourth IGUs 1110, 1120, 1130 and 1140 may be electrically connected to the first to fourth OLED controllers 1210, 1220, 1230 and 1240, respectively. The first to fourth IGUs 1110, 1120, 1130 and 1140 may be connected to the first to fourth OLED controllers 1210, 1220, 1230 and 1240 one-to-one. In detail, the first IGUs 1110 may be connected to the first OLED controller 1210 through a cable, and the second IGU 1120 may be connected to the second OLED controller 1220 through the cable. The third IGUs 1130 may be connected to the third OLED controller 1230 through the cable, and the fourth IGU 1140 may be connected to the fourth OLED controller 1240 through the cable.

The first to fourth IGUs 1110, 1120, 1130 and 1140 may receive image information from the first to fourth OLED controllers 1210, 1220, 1230 and 1240 through the cable and display an image based on the received image information. Each of the first to fourth IGUs 1110, 1120, 1130 and 1140 may receive the same image information from each of the first to fourth OLED controllers 1210, 1220, 1230 and 1240. Therefore, the first to fourth IGUs 1110, 1120, 1130 and 1140 may simultaneously display the same image.

Each of the first to fourth OLED controllers 1210, 1220, 1230 and 1240 may be positioned inside a space formed on an upper side of a window on which a corresponding IGU among the first to fourth IGUs 1110, 1120, 1130 and 1140 is installed. For example, the first OLED controller 1210 may be positioned inside a space formed on an upper side of the window Window A in which the first IGU 1110 is installed.

Each of the first to fourth OLED controllers 1210, 1220, 1230 and 1240 may be accommodated in a space formed inside a side housing of the mobility M, and thus may be electrically connected to a corresponding one of the first to fourth IGUs 1110, 1120, 1130 and 1140 through the cable.

The first to fourth OLED controllers 1210, 1220, 1230 and 1240 may be electrically connected to the switch hub 1300. The first to fourth OLED controllers 1210, 1220, 1230 and 1240 may receive image data from the switch hub 1300. The first to fourth OLED controllers 1210, 1220, 1230 and 1240 may convert the received image data into image information that may be processed by the transparent OLED module disposed inside the first to fourth IGUs 1110, 1120, 1130 and 1140 and transmit the converted image information to the first to fourth IGUs 1110, 1120, 1130 and 1140.

The switch hub 1300 may be connected to a communication controller 1500 through an input port, and may be connected to the first to fourth OLED controllers 1210, 1220, 1230 and 1240 through an output port. The switch hub 1300 may relay between the communication controller 1500 and the first to fourth OLED controllers 1210, 1220, 1230 and 1240 by using Ethernet communication.

In detail, the switch hub 1300 may receive image data from the communication controller 1500 via Ethernet communication. In addition, the switch hub 1300 may convert the received image data into image information that may be processed by the transparent OLED module and transmit the converted image information to the first to fourth OLED controllers 1210, 1220, 1230 and 1240 through Ethernet communication. At this time, the switch hub 1300 may transmit the same image information to the first to fourth OLED controllers 1210, 1220, 1230 and 1240 so that the first to fourth IGUs 1110, 1120, 1130 and 1140 may simultaneously display the same image.

As shown in FIGS. 11 to 13, one switch hub 1300 may be provided in the mobility M. The switch hub 1300 may be positioned inside a space formed on an upper side of a window in which any one of the first to fourth OLED controllers 1210, 1220, 1230 and 1240 is positioned.

The communication controller 1400 may receive image data from the outside and stream the received image data to the first to fourth OLED controllers 1210, 1220, 1230 and 1240 through the switch hub 1300. The communication controller 1400 may receive the image data via wireless communication. The received image data may be stored in a memory of the communication controller 1400. The image data received from the outside may include advertisement image data or subway information, but is not necessarily limited thereto.

The communication controller 1400 may transmit the image data stored in the memory to the switch hub 1300 through Ethernet communication.

The communication controller 1400 may receive the image data from the outside in advance and store the image data in the memory and then output the image data stored in the memory to the switch hub 1300, but is not necessarily limited thereto. The communication controller 1400 may stream the image data received in real time via wireless communication to the transparent OLED module of the IGU 1100 via the switch hub 1300 and the OLED controller 1200.

As shown in FIGS. 11 to 13, one communication controller 1400 may be provided in the mobility M. The communication controller 1400 may be positioned inside a space formed on an upper side of a window in which any one of the first to fourth OLED controllers 1210, 1220, 1230 and 1240 is positioned. In this case, the communication controller 1400 may be positioned inside a space formed on an upper side of a window that is not provided with the switch hub 1300.

Each of the first to fourth OLED controllers 1210, 1220, 1230 and 1240 may include a power board. As shown in FIG. 13, each of the first to fourth OLED controllers 1210, 1220, 1230 and 1240 may supply power supplied from a power source 1310 provided in the mobility M to the first to fourth IGUs 1110, 1120, 1130 and 1140, the switch hub 1300 and the communication controller 1400 by using the power board.

As an example, the first OLED controller 1210 may receive the power from the power source 1310 provided in the mobility M, and may supply the power to the first IGU 1110 and the communication controller 1400 based on the received power. As another example, the second OLED controller 1220 may receive the power from the power source 1310 provided in the mobility M, and may supply the power to the second IGU 1120 and the switch hub 1300 based on the received power.

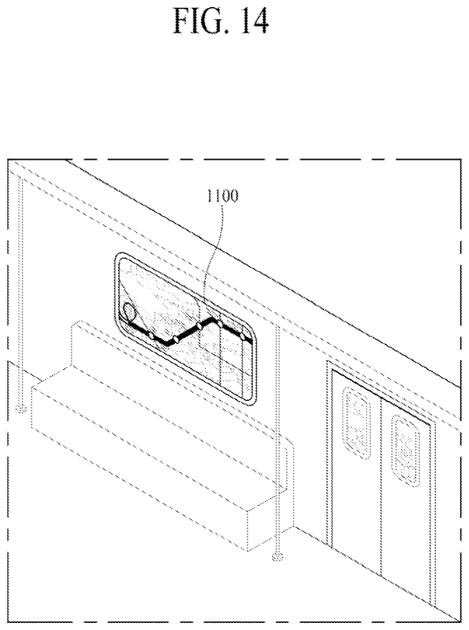

FIG. 14 is a view illustrating an example in which an IGU according to one aspect of the present disclosure is applied to a train.

The IGU 1100 may be installed on a window at one side of the mobility M to display image information. For example, as shown in FIG. 14, the IGU 1100 may be installed on a window at one side of a subway to display subway line information.

The IGU 1100 may include a transparent OLED module that displays an image thereon and transmits external light at the same time, thereby displaying image information without damaging transparency of glass. In addition, the IGU 1100 may make sure of a field of view, thereby making sure of safety even in case of an emergency situation.

According to the present disclosure, the following advantageous effects may be obtained.

The present disclosure includes a transparent OLED panel that displays an image inside an IGU and transmits external light at the same time to make sure of a field of view while providing image information to a user through the IGU, thereby making sure of safety in case of an emergency situation.

Also, in the present disclosure, the UV light shielding film may be provided in the IGU, so that the intensity or amount of UV light incident on the transparent OLED panel may be reduced. Therefore, the present disclosure may reduce the possibility of driving defects due to exposure of the transparent OLED panel to the UV light for a long time, thereby improving reliability.

Also, the present disclosure may include the UV light shielding film therein, so that the UV light shielding film may be prevented from being contaminated or damaged by external factors.

Also, the present disclosure may form a gap space between the UV light shielding film and the transparent OLED panel, thereby further improving a UV light shielding effect.

Also, in the present disclosure, the UV light incident from the outside may be prevented from moving to at least a portion of the cable, the COF and the source PCB by the printing layer. Therefore, the present disclosure may protect the circuit and parts, which are provided in the COF and the source PCB, from the UV light.

Also, in the present disclosure, the plurality of holes through which the cable may pass may be provided in the second spacer disposed in the open area of the first spacer, so that the gap between the first tempered glass or the second tempered glass and the spacer may be prevented from being widened due to the cable.

Also, in the present disclosure, since the second spacer may be detachably provided, the cable, etc. may be easily repaired.

Also, the present disclosure may include the first adhesive structure between the first tempered glass and the source PCB, so that the circuits provided in the source PCB may be prevented from colliding with the first tempered glass due to movement of the mobility.

Also, in the present disclosure, the first adhesive structure and the connector may be disposed to be spaced apart from each other, whereby it is possible to prevent the first adhesive structure from giving any impact to the connector and the cable connected to the connector due to vibration. Therefore, the cable may be prevented from being detached from the connector by vibration.

Also, in the present disclosure, the first adhesive structure and the bonding area may be disposed to be spaced apart from each other, whereby it is possible to prevent the first adhesive structure from giving any impact to the bonded COF due to vibration. Therefore, the present disclosure may prevent a bonding defect from occurring in the COF due to vibration.

Also, in the present disclosure, the first adhesive structure and the active element area may be disposed to be spaced apart from each other, so that heat generated from the plurality of active elements may be prevented from being transferred to the first adhesive structure. Therefore, an adhesive force of the first adhesive structure may be prevented from being weakened due to the heat generated from the active elements.

In the present disclosure, the heat emission structure may be provided with an inclined surface having a gradient similar to that of the COF and the COF comes into contact with the inclined surface, whereby heat generated from the drive IC provided in the COF may be lowered.

Also, in the present disclosure, the pressing structure may press the drive IC toward the heat emission structure to make sure of contact between the drive IC and the lines provided in the COF.

It will be apparent to those skilled in the art that the present disclosure described above is not limited by the above-described aspects and the accompanying drawings and that various substitutions, modifications and variations may be made in the present disclosure without departing from the spirit or scope of the disclosures. Consequently, the scope of the present disclosure is defined by the accompanying claims and it is intended that all variations or modifications derived from the meaning, scope and equivalent concept of the claims fall within the scope of the present disclosure.

What is claimed is:

1. An insulated glass unit comprising:
a first tempered glass and a second tempered glass, which are disposed to face each other;
a transparent OLED module provided between the first tempered glass and the second tempered glass and including a transparent OLED panel for displaying an image and a source printed circuit board (PCB) provided with a driving circuit for driving the transparent OLED panel;
a spacer provided between an edge of the first tempered glass and an edge of the second tempered glass and having a space between the first tempered glass and the second tempered glass; and
a cable having one end electrically connected to the source PCB and another end exposed to the outside by passing through the spacer.

2. The insulated glass unit of claim 1, wherein the transparent OLED panel is fixed to one surface of the first tempered glass by an optical adhesive layer.

3. The insulated glass unit of claim 1, wherein the transparent OLED panel is provided with a plurality of pixels that include a transmissive area and a light emission area.

4. The insulated glass unit of claim 1, further comprising a UV light shielding film provided on one surface of the second tempered glass, which faces the transparent OLED panel.

5. The insulated glass unit of claim 4, wherein the UV light shielding film is spaced apart from the transparent OLED panel and forms a gap space.

6. The insulated glass unit of claim 4, wherein the UV light shielding film overlaps with at least a portion of the transparent OLED panel.

7. The insulated glass unit of claim 1, further comprising:
a first printing layer provided on one surface of the first tempered glass; and
a second printing layer provided on one surface of the second tempered glass, which faces the first tempered glass,
wherein a printing area in which the first printing layer and the second printing layer overlap with the source PCB and a portion of the cable.

8. The insulated glass unit of claim 7, further comprising a UV light shielding film provided on one surface of the second tempered glass, wherein the UV light shielding film does not overlap with the printing area.

9. The insulated glass unit of claim 1, wherein the spacer includes:
a first spacer provided along an edge between the first tempered glass and the second tempered glass and having an open area on at least one side; and
a second spacer provided with a plurality of holes through which the cable passes and disposed in an open area of the first spacer.

10. The insulated glass unit of claim 9, wherein the first spacer includes:
a spacer bar spacing the first tempered glass and the second tempered glass apart from each other to form a space;
a desiccant disposed inside the spacer; and
an adhesive disposed outside the spacer bar to fix the first tempered glass, the second tempered glass and the spacer bar.

11. The insulated glass unit of claim 9, wherein the second spacer is detachable.

12. The insulated glass unit of claim 9, wherein the spacer further includes a sealing layer disposed outside the second spacer to seal the plurality of holes provided in the second spacer.

13. The insulated glass unit of claim 1, wherein the transparent OLED module further includes a chip-on-film (COF) electrically connecting the transparent OLED panel with the source PCB,
wherein the insulated glass unit further comprising a heat emission structure disposed between the first tempered glass and the COF.

14. The insulated glass unit of claim 13, wherein the COF includes a drive IC.

15. The insulated glass unit of claim 13, wherein the heat emission structure has an inclined surface, and is in contact with the COF on the inclined surface.

16. The insulated glass unit of claim 13, wherein the heat emission structure has a surface facing the first tempered glass, which is attached to the first tempered glass by a first adhesive layer.

17. The insulated glass unit of claim 13, wherein the heat emission structure includes a metal material.

18. The insulated glass unit of claim 13, further comprising a pressing structure disposed between the second tempered glass and the COF to press the COF toward the heat emission structure.

19. The insulated glass unit of claim 18, wherein the pressing structure has a surface facing the second tempered glass, which is attached to the second tempered glass by a second adhesive layer.

20. The insulated glass unit of claim 1, further comprising:
a first adhesive structure disposed between the first tempered glass and the source PCB; and
a second adhesive structure disposed between the second tempered glass and the source PCB.

21. The insulated glass unit of claim 20, wherein one surface of the first adhesive structure, which faces the first tempered glass, is adhered to the first tempered glass, and another surface of the first adhesive structure, which faces the source PCB, is adhered to the source PCB to fix the source PCB to the first tempered glass.

22. The insulated glass unit of claim 20, wherein the first adhesive structure is a double-sided foam tape.

23. The insulated glass unit of claim 20, wherein one surface of the second adhesive structure, which faces the second tempered glass, is adhered to the second tempered glass.

24. The insulated glass unit of claim 20, wherein the second adhesive structure is a single-sided foam tape.

25. The insulated glass unit of claim 20, wherein the source PCB includes a connector disposed on a surface facing the first tempered glass and connected with the cable, and
wherein the first adhesive structure is spaced apart from the connector of the source PCB.

26. The insulated glass unit of claim 20, wherein the source PCB includes an active element disposed on a surface facing the first tempered glass, and
wherein the first adhesive structure is spaced apart from the active element of the source PCB.

27. The insulated glass unit of claim 20, wherein the source PCB includes a bonding area bonded to the COF, and
wherein the first adhesive structure is spaced apart from the bonding area of the source PCB.

28. The insulated glass unit of claim 20, wherein the second adhesive structure is spaced apart from an edge of the source PCB.

29. The insulated glass unit of claim 20, wherein the first adhesive structure is thicker than the second adhesive structure.

30. A mobility system comprising:
an insulated glass unit (IGU) installed in at least one window of a mobility and provided with a transparent OLED module between a first tempered glass and a second tempered glass, which are disposed to face each other;
an OLED controller connected to the transparent OLED module provided in the IGU, through a cable; and
a communication controller receiving image data and streaming the received image data to the OLED controller via a switch hub.

31. The mobility system of claim 30, wherein the IGU and the OLED controller are provided as a plurality of IGUs and a plurality of OLED controllers to correspond to each other in one-to-one correspondence, and the communication controller simultaneously transmits the received image data to the plurality of OLED controllers through the switch hub.

32. The mobility system of claim 30, wherein the communication controller receives the image data through wireless communication and transmits the image data through Ethernet communication.

33. The mobility system of claim 30, wherein the transparent OLED module includes:
a transparent OLED panel disposed in a transparent area of the IGU; and
a source PCB disposed in a printing area of the IGU.

34. The mobility system of claim 33, wherein the IGU further includes:
a spacer provided along an edge between the first tempered glass and the second tempered glass; and
a cable having one end electrically connected to the source PCB and the other end exposed to the outside by passing through the spacer.

35. The mobility system of claim 34, wherein the printing area overlaps with the source PCB and a portion of the cable.

36. The mobility system of claim 34, wherein the spacer includes:
a first spacer provided along the edge between the first tempered glass and the second tempered glass having an open area on at least one side; and
a second spacer provided with a plurality of holes through which the cable passes and disposed in the open area of the first spacer.

37. The mobility system of claim 34, wherein the transparent OLED module further includes a chip-on-film (COF) electrically connecting the transparent OLED panel with the source PCB and including a drive IC, and
wherein the IGU further includes a heat emission structure disposed between the first tempered glass and the COF, and a pressing structure disposed between the second tempered glass and the COF to press the COF toward the heat emission structure.

38. The mobility system of claim 34, wherein the IGU further includes:
a double-sided foam tape disposed between the first tempered glass and the source PCB; and
a single-sided foam tape disposed between the second tempered glass and the source PCB.

39. The mobility system of claim 30, wherein the IGU further includes a UV light shielding film provided on one surface of the second tempered glass, which faces the transparent OLED module, and spaced apart from the transparent OLED module to form a gap space.

40. The mobility system of claim 30, wherein the mobility includes a train or subway.
